(19) United States
(12) Patent Application Publication
(10) Pub. No.: US 2002/0061658 A1
(43) Pub. Date: May 23, 2002

(54) Method of forming a semiconductor structure

(75) Inventors: Robertus Mominicus Joseph Verhaar, Eindhoven (NL); Hendrik Hubertus Van Der Meer, Nijmegen (NL)

Correspondence Address: Corporate Patent Counsel, U.S. Philips Corporation, 580 White Plains Road, Tarrytown, NY, 10591, US

(73) Assignee: KONINKLIJKE PHILIPS ELECTRONICS N.V.

(21) Appl. No.: 09/989,250

(22) Filed: Nov. 20, 2001

(30) Foreign Application Priority Data
Nov. 21, 2000 (EP) 00204131.7

(51) Int. Cl. H01L 21/31; H01L 21/469

(52) U.S. Cl. 438/786; 438/782

(57) ABSTRACT

The present invention provides a method of forming a semiconductor structure (10) comprising a substrate (12) having a patterned Oxide-Nitride-Oxide (ONO) insulating layer (22) provided over a portion of the substrate (12). The invention employs an Oxide-Nitride-Silicon structure (38, 40, 42) as the basis for the ONO layer, which has the advantage that the upper silicon sub-layer (42) of the structure is resistant to damage during the photoresist stripping step of a patterning process and is then available for re-oxidizing into an oxide layer forming the upper sub-layer of the required ONO structure.

The present invention relates to a method of forming a semiconductor structure comprising a substrate having a patterned Oxide-Nitride-Oxide insulating layer provided over a portion of the substrate.

An insulating layer in the form of Oxide-Nitride-Oxide (ONO) sub-layers is commonly employed as an insulting layer between a floating gate and a control gate of a nonvolatile memory cell.

Such non-volatile memory cells are commonly integrated onto a semiconductor substrate adjacent to a peripheral structure such as a peripheral transistor. In order to simplify the fabrication process, the layer of, for example, polysilicon serving to form the control gate of the non-volatile memory cell can also be used as part of the peripheral transistor structure, such as the gate thereof.

The above-mentioned fabrication technique is one example of a process where an ONO insulating layer has to be selectively removed from regions of the substrate so as to allow the required peripheral structure to be formed.

Standard prior-art processes have employed the provision of a patterned photoresist on the ONO insulating layer so as to allow selective etching of the ONO layer and thereby enable the formation of the appropriate peripheral structure.

However, disadvantages arise since, once the photoresist has performed its function, it is stripped from the structure and this stripping process serves to remove or at least damage the top oxide layer of the ONO insulating layer. Such problems are accentuated in situations where the top oxide layer of the ONO insulating layer is relatively thin and/or formed through deposition. The attack on this upper oxide portion of the ONO insulating layer therefore represents a particularly problematic feature.

U.S. Pat. No. 6,004,847 discloses a process which serves to limit the above-mentioned problem in that, at the time of depositing a photoresist layer, the insulating layer comprises merely Nitride-Oxide sub-layers, i.e. a NO structure, the upper nitride layer of which is much less damaged than the upper oxide sub-layer of an ONO structure would be during photoresist stripping. In this prior-art document, once the resist has been stripped, an oxide layer is deposited on the Nitride layer so as to form a complete ONO insulating layer structure.

The process and the related structure disclosed in this prior-art document is nevertheless disadvantageously limited with regard to quality and control of the thickness of the layers that can be achieved in the final memory cell structure and peripheral structure.

The present invention therefore seeks to provide a method of forming a semiconductor structure provided with a patterned ONO insulating layer, which exhibits advantages over such known methods and related structures.

According to one aspect of the present invention there is provided a method of forming a semiconductor structure as mentioned above, which method is characterized by the steps of forming an insulating layer comprising an Oxide-Nitride-Silicon layered structure on the substrate, applying a photoresist to the silicon surface as part of a patterning process and stripping the photoresist once a required patterning step has been completed, and subsequently re-oxidizing the silicon layer of the remaining Oxide-Nitride-Silicon structure so as to form an ONO insulating layer structure.

The feature of claim 2 has the advantage of offering a good quality of oxidation of the silicon layer. The features of claims 3 and 4 relate to a particularly advantageous integrated structure benefiting from the present invention. The feature of claim has the advantage that the re-oxidation of the silicon layer serves as a useful vehicle for forming a high voltage oxide layer in the peripheral structure.

The invention is described further hereinafter, by way of example only, with reference to the accompanying drawings in which;

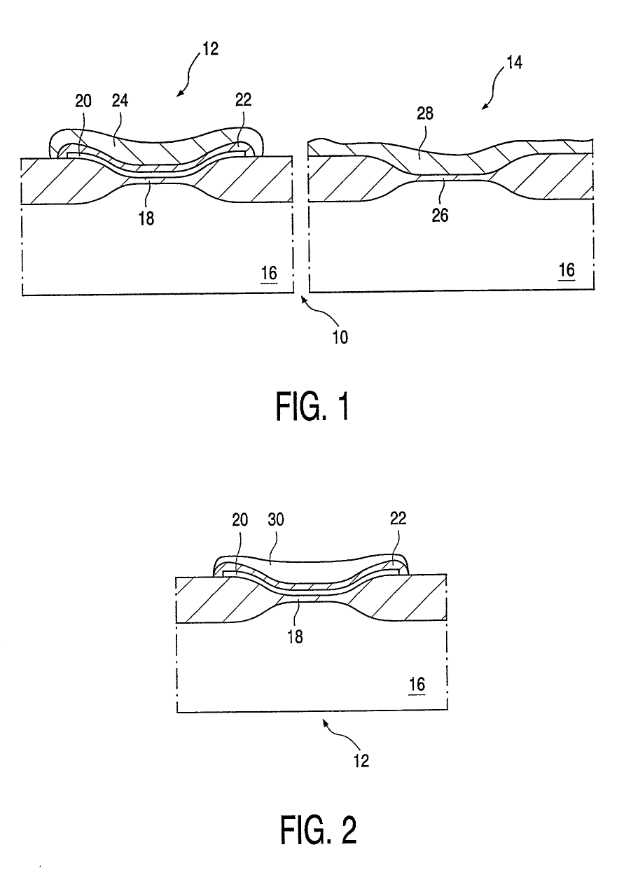

FIG. 1 is a cross-sectional view of a non-volatile memory cell and integrated peripheral transistor structure to be formed in accordance with a method embodying the present invention;

FIG. 2 is a cross-sectional view of an integrated semiconductor structure during the formation of the structure of FIG. 1;

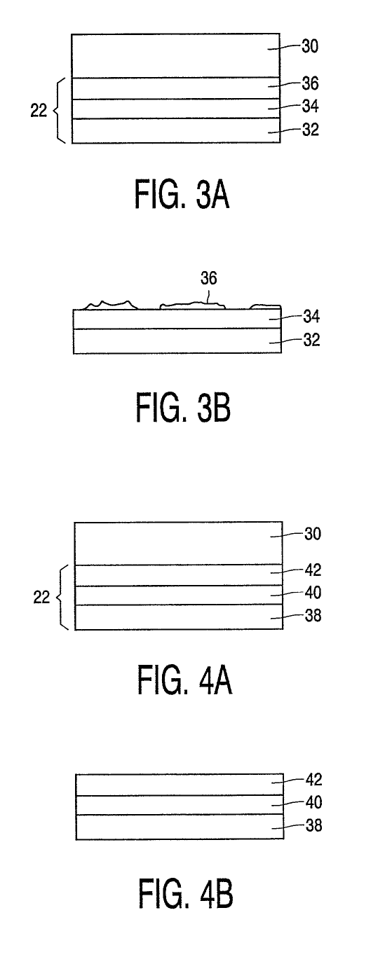

FIGS. 3A and B show an enlarged view of part of the structure of FIG. 2 as arranged according to a method of the prior-art.

FIGS. 4A and 4B show a similarly enlarged view of a structure in accordance with an embodiment of the present invention.

FIG. 1 there shows a cross-sectional view of an integrated semiconductor structure 10 comprising a non-volatile memory cell 12 and an associated peripheral transistor structure 14.

The memory cell 12 and the peripheral transistor 14 share a common substrate 16 while the memory cell 12 is formed, in ascending order as illustrated in the drawing, by a gate oxide layer 18, a floating gate polysilicon layer 20, an ONO insulating layer 22 and a polysilicon control gate 24. It is only the basic features of the peripheral transistor structure 14 that are illustrated in FIG. 1 and, again in ascending order, these comprise a gate oxide 26 formed from a continuation of the oxide layer 18 of the memory cell 12 and also a polysilicon gate layer 28 which comprises an extension of the polysilicon control gate 24 of the memory cell 12. In order to enable for the formation of the peripheral structure such as the peripheral transistor 14 illustrated in FIG. 1, the ONO insulating layer 22 which initially extends laterally over the majority of the integrated structure illustrated in FIG. 1 needs to be patterned, i.e. removed from the regions of the substrate 16 where the peripheral transistor 14 is to be formed.

Such patterning is achieved by means of the provision of a photoresist 30 illustrated in FIG. 2. The photoresist layer 30 is first formed over the ONO layer 22 and then a photolithographic process serves to pattern the photoresist 30 so as to allow for subsequent etching of the ONO layer 22 at locations where no photoresist is present. Once the ONO layer 22 is effectively patterned by such etching, it eventually becomes necessary to strip the photoresist from the upper surface of the ONO layer 22. The illustration provided by FIG. 2 indicates the stage after etching of the ONO insulating layer 22 and just before stripping the photoresist layer 30 from the ONO insulating layer 22.

During stripping the photoresist layer 30 from the ONO insulating layer 22, damage to the upper oxide sub-layer of the ONO structure occurs.

This particular aspect is illustrated further in FIG. 3A and 3B.

FIG. 3A is an enlarged view of a portion of the ONO insulating structure 22 of FIG. 2, in which a portion of the ONO insulating layer 22 with a portion of photoresist 30 thereon is illustrated in greater detail. As will be appreciated, the resist layer 30 actually contacts the upper oxide sub-layer 36 of the ONO insulating layer 22 and, at the time of stripping, serves to remove, and generally damage, the upper oxide sub-layer 36 as illustrated in FIG. 3B in which the same portion of the ONO insulating structure 22 after removal of the photoresist 30 is shown.

According to an embodiment of the present invention, rather than immediately forming the insulating layer as an ONO structure, an insulating layered structure comprising, again in ascending order sub-layers of, respectively. oxide 38, nitride 40 and silicon 42, are provided such that the photoresist 30 is subsequently deposited on the surface of the silicon sub-layer 42. In this case, as illustrated in FIG. 4A, there is no exposed oxide to be attacked during the stripping of the photoresist. The upper silicon sub-layer 42 proves much more resistive to such detrimental attack, so that, after stripping the resist 30, an undamaged Oxide-Nitride-Silicon structure 38, 40, 42 as illustrated in FIG. 4B remains.

This remaining layered structure as illustrated in FIG. 4B is then processed in accordance with the present invention by oxidizing the silicon sub-layer 42 into a thermal oxide so as to obtain a final ONO insulating layer 22 as required by the memory cell 12 of the illustrated embodiment. In addition, the formation of the upper oxide layer at this stage can also assist in the formation of a high-voltage oxide of suitable thickness for the peripheral transistor 14.

It should be appreciated that the important aspect of the present invention relates to the provision of an initial Oxide-Nitride-Silicon insulating layer structure which, subsequent to photoresist stripping, can be readily altered to an ONO insulating layered structure by oxidation of the upper silicon sub-layer, and hence the invention is not restricted to the details of the particular embodiment illustrated herein and relating to one particular form of memory cell arrangement.

1. A method of forming a semiconductor structure comprising a substrate having a patterned ONO insulating layer over a portion thereof, and characterized by the steps of forming an insulating layer comprising an Oxide-Nitride-Silicon layered structure on the substrate, applying a photoresist to the silicon surface as part of a patterning process and stripping the photoresist once a required patterning step has been completed, and subsequently re-oxidizing the silicon layer of the remaining Oxide-Nitride-Silicon structure so as to form an ONO insulating layer structure.

2. A method as claimed in claim 1, wherein the silicon layer comprises an amorphous silicon layer.

3. A method as claimed in claim 1 or 2, wherein a non-volatile memory cell is applied as part of the semiconductor structure, which non-volatile memory cell employs the ONO insulating layer between a floating gate and control gate thereof.

4. A method as claimed in claim 3, wherein the non-volatile memory cell is applied with a control gate formed from a conductive layer which also serves to form part of a peripheral semiconductor structure.

5. A method as claimed in claim 1, 2, 3 or 4, wherein the subsequent oxidation of the silicon sub-layer of the Oxide-Nitride-Silicon insulating layer takes place also to provide a high voltage oxide layer for a peripheral structure.

6. A method as claimed in any one of claims 1 to 5, wherein the silicon layer is re-oxidized into a thermal oxide.
